(19) United States
(12) Patent Application Publication
(10) Pub. No.: US 2026/0016510 A1
(43) Pub. Date: Jan. 15, 2026

(54) CURRENT SENSOR

(71) Applicant: Alps Alpine Co., Ltd., Tokyo (JP)

(72) Inventors: Manabu TAMURA, Miyagi-ken (JP); Yuu KUMAGAI, Miyagi-ken (JP); Junichi HOSOGOE, Miyagi-ken (JP)

(21) Appl. No.: 19/332,687

(22) Filed: Sep. 18, 2025

Related U.S. Application Data
(63) Continuation of application No. PCT/JP2024/006045, filed on Feb. 20, 2024.

(30) Foreign Application Priority Data
Apr. 27, 2023 (JP) 2023-073486

(51) Int. Cl. G01R 15/20; G01R 19/00

(52) U.S. Cl. CPC G01R 15/205; G01R 19/0092

(57) ABSTRACT

A current sensor according to the invention to be attached to a busbar and used includes a magnetic sensor configured to detect a magnetic field generated by a busbar when a current to be measured flows, an insertion hole into which the busbar is insertable, and a main body accommodating the magnetic sensor. The main body includes a stopper portion configured to engage the busbar inserted into the insertion hole at a predetermined position in a Y direction, which is a longitudinal direction of the busbar, and a crush rib configured to fit tightly with a first protruding portion protruding from a plate surface of the busbar, in a state in which a second protruding portion of the busbar engages with the stopper portion. The occurrence of misalignment between the busbar and a magnetic detection element can be suppressed.

### CLAIM OF PRIORITY

This application is a Continuation of International Application No. PCT/JP2024/006045 filed on Feb. 20, 2024, which claims benefit of Japanese Patent Application No. 2023-073486 filed on Apr. 27, 2023. The entire contents of each application noted above are hereby incorporated by reference.

### BACKGROUND OF THE INVENTION

### 1. Field of the Invention

The present invention relates to a current sensor for measuring currents to be measured flowing through various devices that are used to control power systems of vehicles or the like.

### 2. Description of the Related Art

In recent years, current sensors that measure currents to be measured flowing through various devices have been used to control power systems of vehicles provided with the various devices. Such current sensors include busbar-integrated-types and busbar-separate-types that are attached to busbars and used. Busbar-separate type current sensors are preferable in terms of standardization and cost reduction. However, in such a busbar-separate-type current sensor, a busbar and a magnetic sensor (magnetic detection element) are disposed at a predetermined distance from each other, and it is difficult to maintain this positional relationship. Accordingly, measurement accuracy may deteriorate due to such a misalignment between the busbar and the magnetic sensor. Therefore, busbar-separate-type current sensors that include mechanisms for suppressing misalignment between busbars and magnetic sensors have been proposed.

For example, Japanese Unexamined Patent Application Publication No. 2010-14477 describes a current sensor that is attached to a busbar and used in order to stabilize the distance between a magnetic sensor and the busbar to enable high-precision current detection. The current sensor in Japanese Unexamined Patent Application Publication No. 2010-14477 includes, inside an annular outer shell part of a non-magnetic case, a first pressing means that presses a non-magnetic holding member that holds a magnetic sensor against a partition wall, and a second pressing member that presses a busbar inserted into an insertion portion against the partition wall.

The current sensor in Japanese Unexamined Patent Application Publication No. 2010-14477 stabilizes the distance between the magnetic sensor and the busbar by using the pressing means that press the magnetic sensor and the busbar against the partition wall. However, it is difficult to apply sufficient force by using the pressing means in the current sensor, and this causes a misalignment between the magnetic detection element and the busbar when the busbar is inserted into the insertion portion or when the busbar inserted into the insertion portion is fastened at a predetermined position with a screw. In addition, when the pressing force (urging force) of the pressing means decreases due to heat, vibration, or the like from the busbar, a misalignment is likely to occur. The present invention provides a current sensor that is to be attached to a busbar and achieves reduced misalignment between the busbar and a magnetic detection element. In addition, the present invention provides a current sensor that enables a reduced misalignment between the magnetic detection element and the busbar even when a means for attaching the current sensor to the busbar deteriorates due to effects of heat generated by the current sensor or the like.

### SUMMARY OF THE INVENTION

A device according to an aspect of the invention for solving the above-described problems includes the following structures. A current sensor includes a magnetic sensor configured to detect a magnetic field generated by a busbar when a current to be measured flows, and a main body accommodating the magnetic sensor. The main body includes an insertion hole into which the busbar is insertable, a stopper portion configured to engage the busbar inserted into the insertion hole in the busbar at a predetermined position in a longitudinal direction, and a crush rib configured to fit tightly with a first protruding portion protruding from one plate surface of the busbar, in a state in which the busbar engages with the stopper portion.

When the busbar is inserted into the insertion hole, the first protruding portion formed in the plate surface is press-fitted while crushing the crush rib provided in the main body, thereby enabling the crush rib and the first protruding portion to be tightly fitted together when the busbar is inserted into the insertion hole. Accordingly, in a state in which the busbar engages with the stopper portion, the busbar can be fixed tightly to the main body at the predetermined position. As a result, misalignment between the busbar and the magnetic sensor can be reduced when the busbar is inserted into the insertion hole, the busbar is fastened with a screw, or in other cases.

The stopper portion may protrude from a first inner surface in an inner surface of the insertion hole, the first inner surface facing the one plate surface of the busbar, and the stopper portion may engage with the busbar when the stopper portion comes into contact with a second protruding portion protruding from the one plate surface of the busbar.

In a state in which the stopper portion protruding from the first inner surface of the sensor body comes into contact with the second protruding portion protruding from the one plate surface of the busbar, and the second protruding portion hits the stopper portion, the first protruding portion and the crush rib may be tightly fitted together, and thereby the busbar can be fixed at a predetermined position in the insertion hole.

The stopper portion may be an opening surface surrounding an opening of the insertion hole, and may engage with the busbar when the stopper portion comes into contact with a second protruding portion protruding from an end surface of the busbar in a width direction.

By using the opening surface surrounding the opening of the insertion hole, the busbar can be engaged at a predetermined position with the simple structure.

In the current sensor, in a state in which the stopper portion engages with the busbar at the predetermined position, the magnetic sensor may be located to face the other plate surface of the busbar. A second inner surface in an inner surface of the insertion hole, the second inner surface facing the other plate surface of the busbar, may have a horizontal portion formed in a plane shape parallel to a first inner surface having the crush rib, the horizontal portion extending from one opening in the insertion hole toward the inside of the insertion hole, and a tapered portion that is formed such that a distance with respect to the first inner surface becomes shorter, from the other opening of the insertion hole toward the inside of the insertion hole. The horizontal portion and the tapered portion may be adjacent to each other with a boundary ridge line therebetween, and the boundary ridge line may be provided, in an extending direction of the busbar, between a contact portion at which the stopper portion comes into contact with the busbar and a tightly fitted portion at which the crush rib is tightly fitted with the busbar.

By providing the horizontal portion and the tapered portion in the second inner surface of the insertion hole and disposing the boundary ridge line provided therebetween between the contact portion and tightly fitted portion, changes in the position of the magnetic sensor and the busbar when the crush rib deteriorates overtime due to effects of heat generated by the busbar or other factors can be reduced. In other words, the boundary ridge line functions as a fulcrum when the busbar moves, thereby suppressing misalignment of the busbar. In addition, by providing the tapered portion, the height of the other opening increases, and thus the operability in inserting the busbar into the insertion hole can be increased.

When viewed in a direction in which the busbar and the magnetic sensor are stacked, the boundary ridge line may overlap the magnetic sensor. By providing the magnetic sensor in the vicinity of the boundary ridge line, misalignment between the busbar and the magnetic sensor can be reduced.

When viewed in a direction in which the busbar and the magnetic sensor are stacked, the stopper portion, the boundary ridge line, and the magnetic sensor may overlap each other. By disposing the stopper portion at a position overlapping the boundary ridge line and the magnetic sensor in the stacking direction, movement of the busbar toward the stopper portion side can be suppressed, and thus misalignment between the busbar and the magnetic sensor can be reduced.

A current sensor includes an elongated plate-shaped busbar through which a current to be measured flows, a magnetic sensor configured to detect a magnetic field generated by the busbar when the current to be measured flows, and a main body accommodating the magnetic sensor. The busbar includes a first protruding portion protruding from one plate surface, and an engaging portion configured to engage the busbar inserted into an insertion hole at a predetermined position, the main body includes the insertion hole into which the busbar is insertable, and a crush rib configured to fit tightly with the first protruding portion of the busbar, the crush rib formed in a first inner surface inside the insertion hole, the first inner surface facing the one plate surface of the busbar, and a stopper portion configured to engage with the engaging portion of the busbar. By inserting the busbar into the insertion hole, the first protruding portion and the crush rib tightly fit with each other, the engaging portion and the stopper portion come in contact with each other, and in a state in which the magnetic sensor is located to face the other plate surface of the busbar, the busbar is attached to the main body.

In a state in which the busbar inserted into the insertion hole engages with the stopper portion, the first protruding portion in the plate surface of the busbar and the crush rib tightly fit with each other, and thereby the busbar can be attached to the main body at the predetermined position.

The busbar may include a fitting protruding portion that protrudes in a width direction of the busbar at a portion where the fitting protruding portion is disposed in the insertion hole and near the other opening, in a state in which the busbar is inserted into the insertion hole and the engaging portion of the busbar engages with the stopper portion, and the insertion hole of the main body may be formed such that a dimension in a width direction increases from the one opening toward the other opening, the width dimension of the one opening may be approximately the same as the width dimension of the busbar at a portion in which the fitting protruding portion is not provided, and the width dimension of the other opening may be approximately the same as the width dimension of the busbar including the fitting protruding portion. In a state in which the engaging portion of the busbar engages with the stopper portion of the main body, the busbar fits with both opening portions, and thereby the position of the busbar in the width direction can be determined and misalignment between the busbar and the magnetic sensor can be reduced.

The busbar may include a narrow portion between the first protruding portion and the engaging portion, the narrow portion being narrower in a width dimension than other portions, and the magnetic sensor may be disposed at a position facing the narrow portion. By providing the narrow portion in the busbar, magnetic fields generated around the busbar when current to be measured flows through the busbar become stronger, and thus the measurement accuracy of the current sensor can be increased. In addition, when the current sensor detects an alternating current, the occurrence of degradation of frequency response due to skin effect can be suppressed.

In a current sensor according to an aspect of the invention, by inserting a busbar into an insertion hole, a first protruding portion of the busbar and a crush rib of a main body tightly fit with each other, and in a state in which the busbar is in contact with a stopper portion of the main body, the busbar is attached to the main body. With such a structure, since the busbar and the main body tightly fit with each other when the busbar is attached to the main body at the predetermined position, misalignment between the busbar and the magnetic sensor can be reduced. In addition, by providing a horizontal portion and a tapered portion in a second inner surface in an insertion hole and disposing a boundary ridge line provided therebetween between an engaging portion and a crush rib in a busbar extending direction, the boundary ridge line can function as a fulcrum of the busbar. Accordingly, the occurrence of misalignment between the busbar and the magnetic sensor when the crush rib deteriorates due to heat, vibration, or the like can be suppressed.

### BRIEF DESCRIPTION OF THE DRAWINGS

FIG. 1A is a perspective view of a current sensor and a busbar according to a first embodiment;

FIG. 1B is a perspective view of a current sensor to which a busbar is attached;

FIG. 2A is a cross-sectional view of a current sensor taken along line IIA-IIA in FIG. 1B;

FIG. 2B is a plan view of the current sensor in FIG. 2A;

FIG. 3A is a cross-sectional view of a current sensor according to a modification;

FIG. 3B is a plan view of the current sensor in FIG. 3A;

FIG. 4A is a schematic view illustrating a positional relationship between a busbar and a main body when the busbar is inserted;

FIG. 4B is a cross-sectional view of a current sensor taken along line IVB-IVB in FIG. 4A;

FIG. 5A is a schematic view illustrating a positional relationship between a busbar and a main body when a first protruding portion of the busbar comes into contact with a crush rib;

FIG. 5B is a cross-sectional view of the current sensor taken along line VB-VB in FIG. 5A;

FIG. 6A is a schematic view illustrating a positional relationship between a busbar and a main body when the busbar is inserted to a predetermined position;

FIG. 6B is a cross-sectional view of the current sensor taken along line VIB-VIB in FIG. 6A;

FIG. 7A is a schematic view illustrating a positional relationship between a busbar and a main body when the busbar is inserted into a current sensor according to a modification;

FIG. 7B is a cross-sectional view of the current sensor taken along line VIIB-VIIB in FIG. 7A;

FIG. 7C is a front view of the current sensor in FIG. 7A;

FIG. 8 is a plan view of a current sensor schematically illustrating a structure for suppressing the occurrence of displacement of a busbar in an X direction;

FIG. 9 is a cross-sectional view of a current sensor according to a second embodiment;

FIG. 10 is a cross-sectional view of a current sensor according to a modification;

FIG. 11 is a cross-sectional view schematically illustrating a busbar to be fastened to a stepped portion;

FIG. 12 is a cross-sectional view illustrating a simulation of the current sensor according to the embodiment;

FIG. 13 is a cross-sectional view illustrating a simulation of a current sensor according to a comparative example;

FIG. 14A is a graph illustrating results regarding the embodiment (Z1 direction, without crush rib damage);

FIG. 14B is a graph illustrating results regarding the embodiment (Z1 direction, with crush rib damage);

FIG. 15A is a graph illustrating results regarding a comparative example (Z1 direction, without crush rib damage);

FIG. 15B is a graph illustrating results regarding the comparative example (Z1 direction, with crush rib damage);

FIG. 16A is a graph illustrating results regarding the embodiment (Z2 direction, without crush rib damage);

FIG. 16B is a graph illustrating results regarding the embodiment (Z2 direction, with crush rib damage);

FIG. 17A is a graph illustrating results regarding the comparative example (Z2 direction, without crush rib damage); and

FIG. 17B is a graph illustrating results regarding the comparative example (Z2 direction, with crush rib damage).

### DESCRIPTION OF THE PREFERRED EMBODIMENTS

Hereinafter, embodiments of the present invention will be described with reference to the attached drawings. In each drawing, the same numerals are given to the same components, and their descriptions are omitted. Reference coordinates are shown in each drawing as appropriate to indicate the positional relationship of each component. In the reference coordinates, a width direction of a busbar is referred to as an X direction, a busbar extending direction is referred to as a Y direction, and a direction that is orthogonal to the X direction and the Y direction is referred to as a Z direction. The X direction denotes a direction of a sensitivity axis of a magnetic sensor, and the Y direction and the Z direction are orthogonal to the sensitivity axis.

### First Embodiment

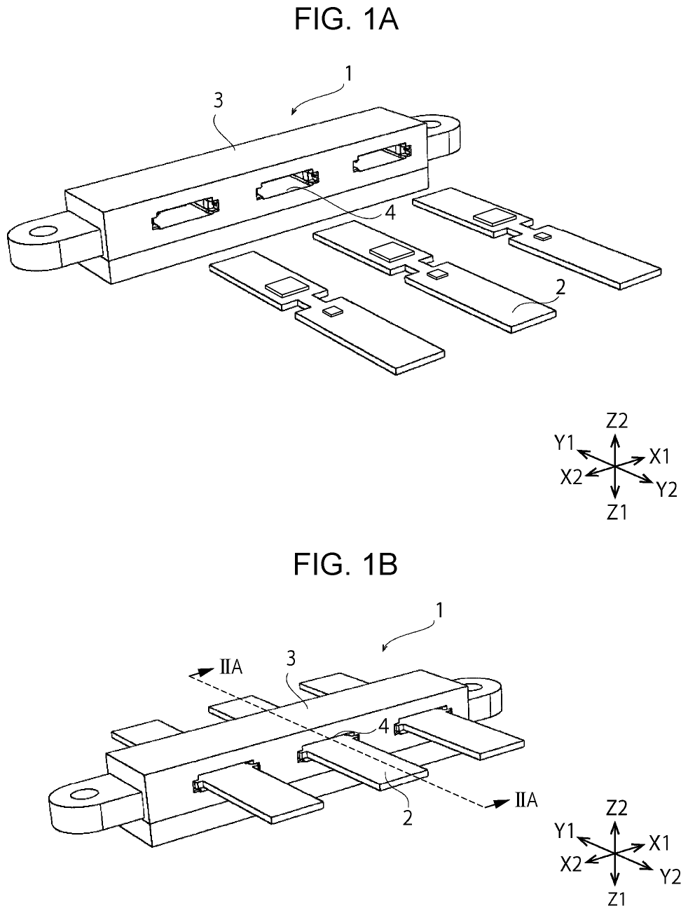

FIG. 1A is a perspective view of a current sensor 1 and a busbar 2 according to the embodiment, and FIG. 1B is a perspective view of the current sensor 1 to which the busbar 2 is attached. As illustrated in the drawings, the current sensor 1 is a busbar-separate-type current sensor in which the busbar 2 is inserted into an insertion hole 4 of a main body 3, and the busbar 2 is not insert-molded to the main body 3.

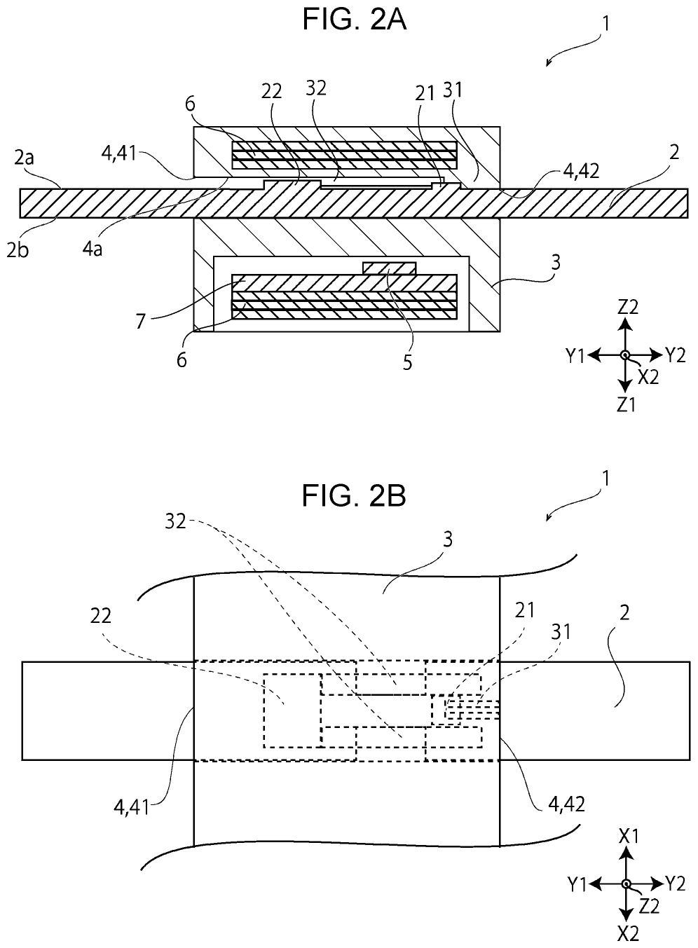

FIG. 2A is a cross-sectional view of the current sensor 1 taken along line IIA-IIA in FIGS. 1B and 1s a view schematically illustrating a structure of the current sensor 1. FIG. 2B is a plan view schematically illustrating a structure of the current sensor 1. The busbar 2 has an elongated plate-shape, and has a plate surface 2b that faces a magnetic sensor 5. The busbar 2 has a first protruding portion 21 and a second protruding portion (engaging portion) 22 at different positions in the Y direction, which is the extending direction. The first protruding portion 21 and the second protruding portion 22 are both formed to protrude from a plate surface 2a. The first protruding portion 21 and the second protruding portion 22 are provided to attach and hold the busbar 2 inserted into the insertion hole 4 of the main body 3 at a predetermined position.

In a state in which the busbar 2 is attached to the predetermined position of the insertion hole 4, the first protruding portion 21 and the second protruding portion 22 are disposed inside the insertion hole 4, and both ends of the busbar 2 protrude from an opening 41 on a Y1 side and an opening 42 on a Y2 side of the insertion hole 4.

The main body 3 has the insertion hole 4 through which the busbar 2 can be inserted, a crush rib 31, and a stopper portion 32. The crush rib 31 is one of surfaces in the insertion hole 4, and is formed in a first inner surface 4a that faces one plate surface 2a of the busbar 2. In a state in which the busbar 2 engages with the stopper portion 32, the crush rib 31 fits tightly with the first protruding portion 21 of the busbar 2. The stopper portion 32 protrudes from the first inner surface 4a in the insertion hole 4. When the busbar 2 is inserted into the insertion hole 4, the second protruding portion 22 protruding from the one plate surface 2a hits and comes into contact with the stopper portion 32, thereby engaging the busbar 2 at a predetermined position in the Y direction, which is the extending direction of the busbar 2. In a state in which the stopper portion 32 is engaging with the busbar 2, the magnetic sensor 5 is located to face the other plate surface 2b of the busbar 2.

When the busbar 2 is inserted into the insertion hole 4 of the main body 3, the first protruding portion 21 of the busbar 2 is moved while crushing a part of the crush rib 31 of the main body 3, thereby enabling the first protruding portion 21 and the crush rib 31 to be tightly fitted together. The insertion of the busbar 2 into the insertion hole 4 is completed in a state in which the second protruding portion 22 of the busbar 2 and the stopper portion 32 of the main body 3 are in contact with each other at the predetermined position in the Y direction, and the busbar 2 is attached to the main body 3.

The crush rib 31 is provided in the vicinity of the opening 42 on the Y2 side. Accordingly, even when a part of the crush rib 31 is crushed and debris is generated, such debris is unlikely to move to the busbar 2 in the vicinity of the opening 41 on the Y1 side. In addition, the first protruding portion 21, which tightly fits with the crush rib 31, stops at a position in front of the opening 42 on the Y2 side in the insertion hole 4, and thus the crush rib 31 is not likely to be scraped off. Accordingly, the debris is less likely to affect welding or other processing of fastening of the busbar 2 that is in the vicinity of the opening 41 on the Y1 side and the opening 42 on the Y2 side to another member.

The busbar 2 in FIG. 2A and FIG. 2B has two protruding portions; however, the busbar 2 may include three or more protruding portions. Instead of the second protruding portion 22, a concave portion may be formed in the plate surface 2a, and the busbar 2 may be engaged at a predetermined position in the Y direction by fitting the concave portion with a convex portion formed in the first inner surface 4a of the insertion hole 4 of the main body 3. Such a structure reduces the amount of metal used for the busbar 2.

In the main body 3, the magnetic sensor 5, which is disposed to face the busbar 2, and a magnetic shield 6 are disposed. The magnetic sensor 5 includes a magnetoresistance effect element and detects a magnetic field that is generated by the busbar 2 when a current to be measured flows. The magnetoresistance effect element may be, for example, a giant magnetoresistance effect element (GMR element), an anisotropic magnetic resistance effect element (AMR element), a tunneling magnetoresistance element (TMR element), a Hall element, or other elements. The magnetic sensor 5 is mounted on a substrate 7, and the substrate 7 is attached to the main body 3.

The busbar 2 is held in a state in which the first protruding portion 21 and the crush rib 31 are tightly fitted together and the second protruding portion 22 and the stopper portion 32 are in contact with each other. In this state, the magnetic sensor 5 is disposed at a position facing a portion of the busbar 2 between the first protruding portion 21 and the second protruding portion 22.

The magnetic shield 6 includes, for example, a plurality of metal plates of the same shape that are stacked. By providing the magnetic shield 6, external magnetic noise to the magnetic sensor 5 is reduced, thereby increasing the measurement accuracy of the magnetic sensor 5. In the current sensor 1, the plate-shaped magnetic shields 6 are disposed on both sides of the magnetic sensor 5 in the Z direction. The magnetic shield 6 on the Z2 side is insert-molded in the main body 3, and the magnetic shield 6 on the Z1 side is disposed on a surface opposite to the surface of the substrate 7 on which the magnetic sensor 5 is disposed. Instead of the plate-shaped magnetic shield 6, a U-shaped or C-shaped (core-shaped) magnetic shield may be used.

By aligning the width of the insertion hole 4 with the width of the busbar 2, the position of the busbar 2 in the X direction in the main body 3 can be determined. By bringing the second protruding portion 22 of the busbar 2 and the stopper portion 32 of the main body 3 in contact with each other, the busbar 2 is engaged at a step in which the busbar 2 has been inserted to the predetermined position, and thereby determining the position of the busbar 2 in the main body 3 in the Y direction. In the state in which the busbar 2 has been inserted to the predetermined position, by tightly fitting the first protruding portion 21 of the busbar 2 and the crush rib 31 of the main body 3, the position of the busbar 2 in the Z direction in the main body 3 can be determined.

Although it has been described in the above description that the width of the insertion hole 4 and the width of the busbar 2 are aligned, actually, the dimensions are regulated to some extent such that the width of the insertion hole 4 is larger than the width of the busbar 2 and no significant looseness occurs between the insertion hole 4 and the busbar 2. If the width of the insertion hole 4 and the width of the busbar 2 are exactly the same, the frictional resistance generated when the busbar 2 is inserted into the insertion hole 4 becomes very large. If the frictional resistance during insertion becomes large, the busbar 2 may be deformed when inserted into the insertion hole 4 or the inner surface of the insertion hole 4 may be scraped by the busbar 2, causing debris to be generated.

As described above, the busbar 2 can be attached to the main body 3 to the predetermined position in the main body 3 by inserting the busbar 2 into the insertion hole 4 of the main body 3. In a state in which the busbar 2 is attached to the main body 3, the first protruding portion 21 of the busbar 2 and the crush rib 31 of the main body 3 are tightly fitted together. Accordingly, it is possible to suppress the occurrence of misalignment of the busbar 2 in the main body 3 during attachment or misalignment during fastening to another component after attachment.

### Modification 1

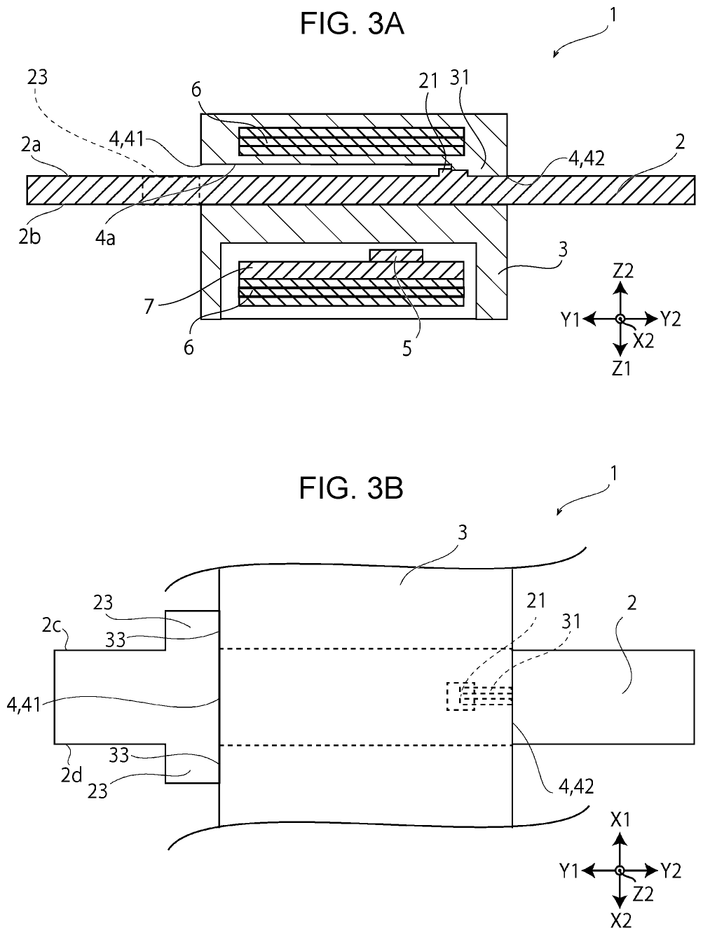

FIG. 3A is a cross-sectional view schematically illustrating a structure of the current sensor 1 according to a modification. FIG. 3B is a plan view of the current sensor 1 in FIG. 3A. The current sensor 1 according to the modification includes a second protruding portion 23 that protrudes from each of a side surface 2c and a side surface 2d of the busbar 2 in the width direction (X direction), instead of the second protruding portion 22 protruding from the plate surface 2a. When the busbar 2 is inserted into the insertion hole 4, the second protruding portion 23 hits an opening surface 33 of the main body 3, thereby engaging the busbar 2 in the main body 3 at a predetermined position. In a state in which the busbar 2 is engaged in the main body 3 at the predetermined position by the second protruding portion 23 and the opening surface 33, the first protruding portion 21 of the busbar 2 and the crush rib 31 of the main body 3 are tightly fitted together. The opening surface 33 is a surface in the outer surface of the main body 3 that surrounds the opening 41 of the insertion hole 4.

As described above, in the current sensor 1 according to the modification, the opening surface 33 of the main body 3 is in contact with the second protruding portion 23 of the busbar 2 to engage the busbar 2, and therefore the stopper portion 32 can be omitted from the main body 3. Accordingly, the structure of the main body 3 can be further simplified.

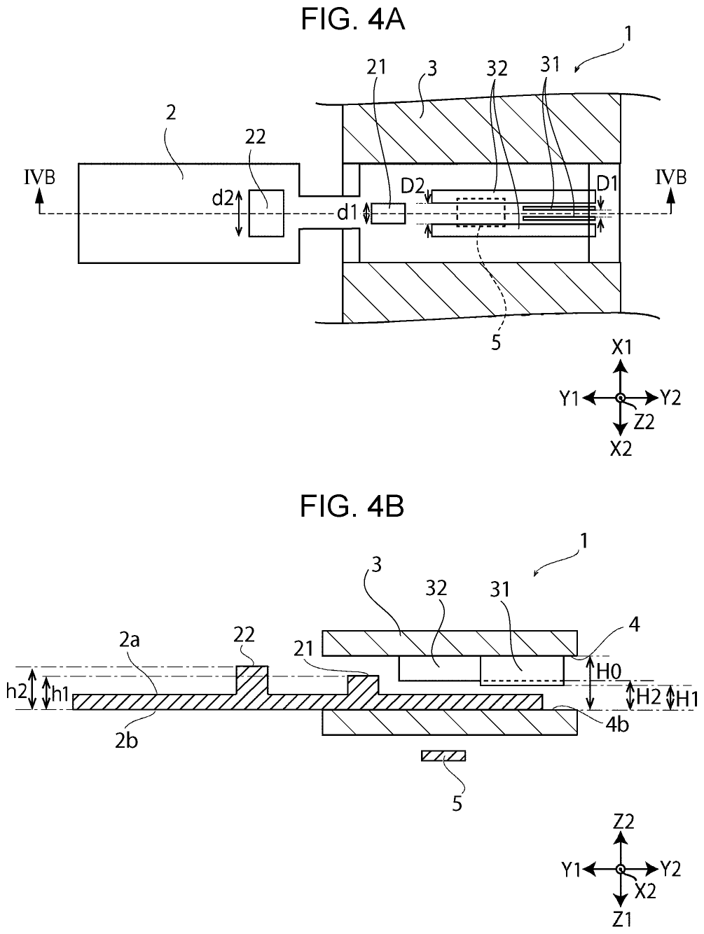

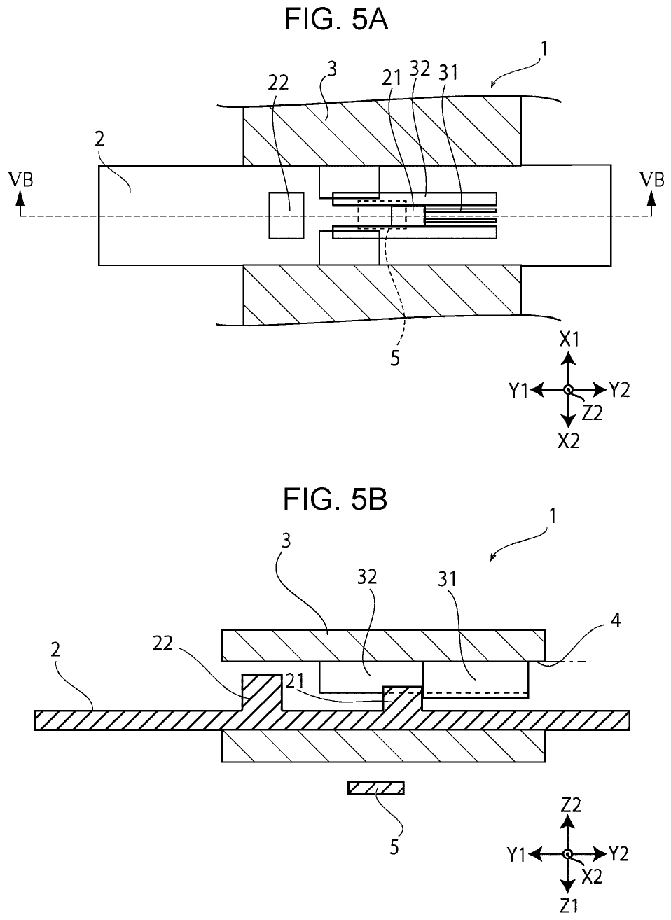

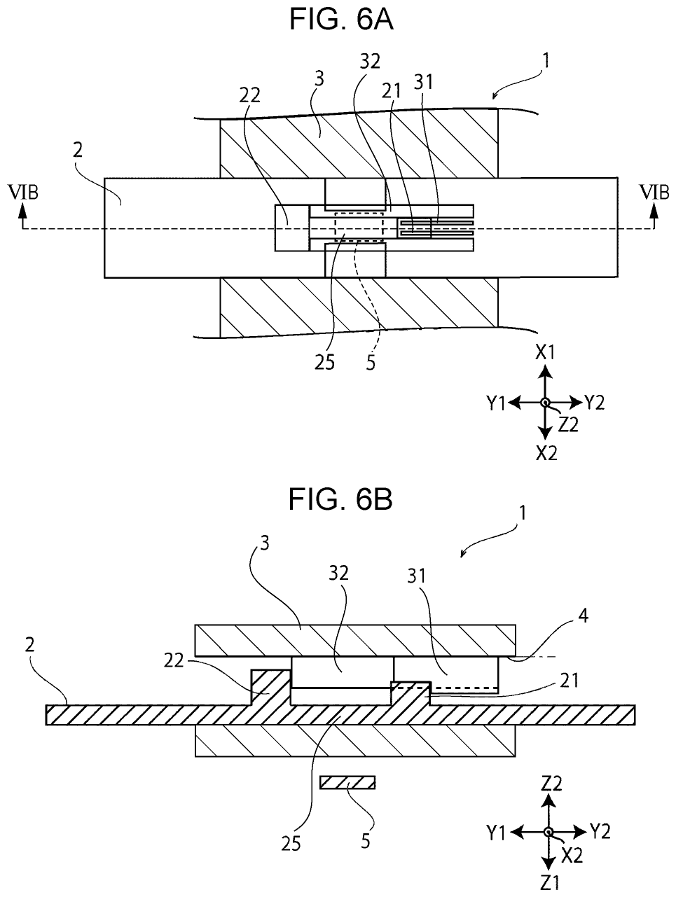

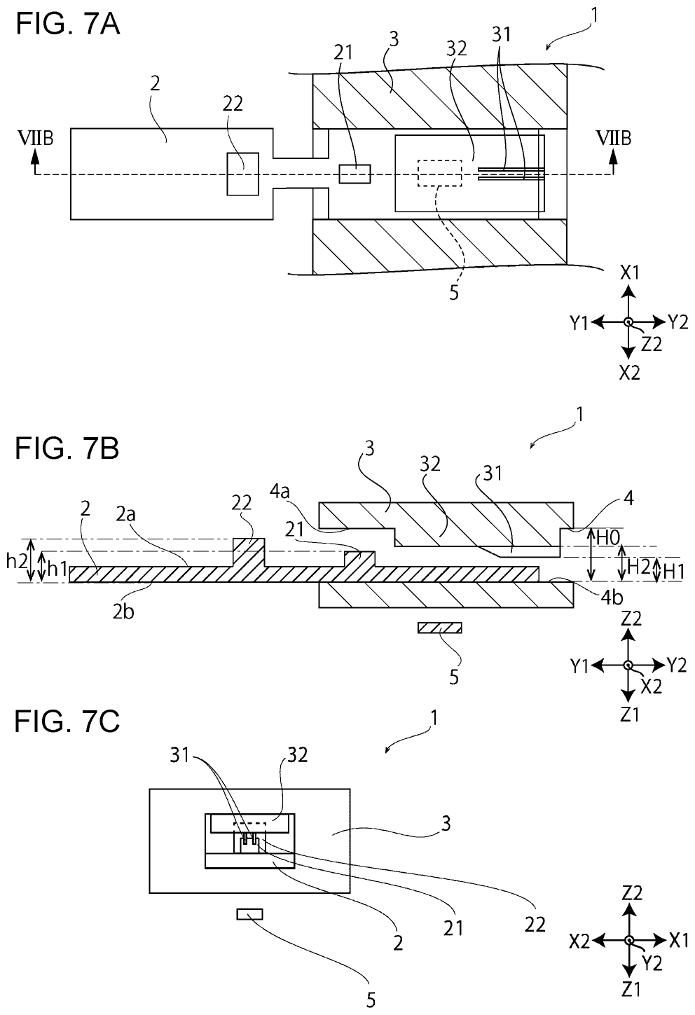

FIG. 4A is a schematic view illustrating a positional relationship between the busbar 2 and the main body 3 when the busbar 2 is inserted. In this drawing, components other than the magnetic sensor 5 are illustrated as solid lines in order to illustrate the positional relationship between the components when viewed in the Z direction. FIG. 4B is a cross-sectional view schematically illustrating a structure of the current sensor 1 taken along line IVB-IVB in FIG. 4A. In FIG. 5A, FIG. 6A, and FIG. 7A, similarly, components are illustrated as solid lines for the sake of convenience in illustrating the positional relationship.

As illustrated in FIG. 4A, the first protruding portion 21 and the second protruding portion 22 in the busbar 2 are rectangular protruding portions in plan view. In addition, each of the crush rib 31 and the stopper portion 32 in the main body 3 includes two rectangular protruding portions with the Y direction as the longitudinal direction.

The crush rib 31 is designed to have a dimension in the X direction such that the crush rib 31 has a strength to deform (be crushed) when the crush rib 31 comes into contact with the first protruding portion 21 and is further pushed in the Y2 direction. In addition, the stopper portion 32 is designed to have a dimension in the X direction such that the stopper portion 32 has a strength not to deform (not to be crushed) when the stopper portion 32 comes into contact with the second protruding portion 22 and is further pushed in the Y2 direction. The crush rib 31 is disposed between the two protruding portions of the stopper portion 32, and in the X direction, a width d1 of the first protruding portion 21 of the busbar 2, a width d2 of the second protruding portion 22, a width D1 between the inner sides of the two protruding portions of the crush rib 31, and a width D2 between the inner sides of the two protruding portions of the stopper portion 32 satisfy a relationship D1<d1<D2<d2.

In addition, as illustrated in FIG. 4B, in the current sensor 1, in the Z direction, a height h1 of the first protruding portion 21 from the plate surface 2b, a height h2 of the second protruding portion 22 from the plate surface 2b, a height H0 of the insertion hole 4, a height H1 of a space between a second inner surface 4b of the insertion hole 4 that faces the one plate surface 2a of the busbar 2 and the crush rib 31, and a height H2 of a space between the second inner surface 4b and the stopper portion 32 satisfy a relationship H1<H2<h1<h2<H0.

The width d1 of the first protruding portion 21 of the busbar 2 is less than the width D2 between the two rectangular protruding portions of the stopper portion 32. Accordingly, the first protruding portion 21 having the height h1 in the busbar 2 passes through the insertion hole 4 having the height H0 between the two rectangular protruding portions of the stopper portion 32 without interfering with the stopper portion 32 until the first protruding portion 21 comes into contact with the crush rib 31 in the insertion hole 4.

FIG. 5A is a schematic view illustrating a positional relationship between the busbar 2 and the main body 3 when the first protruding portion 21 of the busbar 2 comes into contact with the crush rib 31. FIG. 5B is a cross-sectional view schematically illustrating a structure of the current sensor 1 taken along line VB-VB in FIG. 5A. FIG. 6A is a schematic view illustrating a positional relationship between the busbar 2 and the main body 3 when the busbar 2 is inserted to a predetermined position. FIG. 6B is a cross-sectional view schematically illustrating a structure of the current sensor 1 taken along line VIB-VIB in FIG. 6A.

The height h1 of the first protruding portion 21 is greater than the height H1 of a space in a portion in the insertion hole 4 in which the crush rib 31 is provided. Accordingly, from the position shown in FIG. 5A to the position shown in FIG. 6A, the first protruding portion 21 is moved while crushing a part of the crush rib 31, thereby maintaining the state in which the first protruding portion 21 is in contact with the crush rib 31 in the Z direction. With this structure, the busbar 2 is press-fitted into the insertion hole 4, and the first protruding portion 21 of the busbar 2 and the crush rib 31 of the main body 3 are tightly fitted together.

As a result, in the state in which the second protruding portion 22 is in contact with the stopper portion 32, by tightly fitting the first protruding portion 21 and the crush rib 31, the position of the busbar 2 in the main body 3 in the Z direction can be fixed. In addition, by the engagement between the second protruding portion 22 and the stopper portion 32, the position of the busbar 2 in the Y direction in the main body 3 can be fixed. Furthermore, by aligning the widths of the busbar 2 and the insertion hole 4 in the X direction, the position of the busbar 2 in the X direction in the main body 3 can be determined.

As illustrated in FIG. 6A and FIG. 6B, the busbar 2 includes a narrow portion 25 between the first protruding portion 21 and the second protruding portion 22. The narrow portion 25 is narrower in a width dimension in the X direction than other portions. The magnetic sensor 5 is disposed at a position to face the narrow portion 25 in a state in which the busbar 2 is attached to the main body 3 at the predetermined position. In the vicinity of the narrow portion 25, when a current to be measured flows through the busbar 2, a magnetic field that is stronger than that in other portions is generated. Accordingly, the magnetic sensor 5 can efficiently detect the magnetic field generated when the current to be measured flows through the busbar 2. In addition, when the magnetic sensor 5 detects an alternating current that flows through the busbar 2, the occurrence of degradation of frequency response due to skin effect can be suppressed.

### Modification 2

FIG. 7A is a schematic view illustrating a positional relationship between the busbar 2 and the main body 3 when the busbar 2 is inserted. FIG. 7B is a cross-sectional view schematically illustrating a structure of the current sensor 1 taken along line VIIB-VIIB in FIG. 7A. FIG. 7C is a front view of the current sensor 1 in FIG. 7A as viewed in the Y1 direction from the Y2 side. As illustrated in FIG. 7A, the structures of the first protruding portion 21 and the second protruding portion 22 in the busbar 2 are similar to those illustrated in FIG. 4A. This modification differs from the structure illustrated in FIG. 4A in that the stopper portion 32 in the main body 3 is a single rectangular protruding portion, and the crush rib 31 is provided to protrude not from the first inner surface 4a in the insertion hole 4 but from the stopper portion 32.

As illustrated in FIG. 7B, in the current sensor 1 according to the modification, in the Z direction, the height h1 of the first protruding portion 21, the height h2 of the second protruding portion 22, the height H0 of the insertion hole 4, the height H1 of the space between the second inner surface 4b of the insertion hole 4, which faces the one plate surface 2a of the busbar 2, and the crush rib 31, and the height H2 of the space between the second inner surface 4b and the stopper portion 32 satisfy a relationship H1<h1<H2<h2<H0.

In this modification, the height h1 of the first protruding portion 21 is less than the height H2 of the space. Accordingly, the first protruding portion 21 having the height h1 in the busbar 2 passes through the space having the height H2 without interfering with the stopper portion 32 until the first protruding portion 21 comes into contact with the crush rib 31 in the insertion hole 4.

As illustrated in FIG. 7C, when viewed from Y2 in the Y1 direction, a part of the first protruding portion 21 of the busbar 2 and a part of the crush rib 31 of the main body 3 overlap each other. Accordingly, in a state in which the second protruding portion 22 of the busbar 2 is in contact with the stopper portion 32 of the main body 3, the first protruding portion 21 of the busbar 2 and the crush rib 31 of the main body 3 are tightly fitted together.

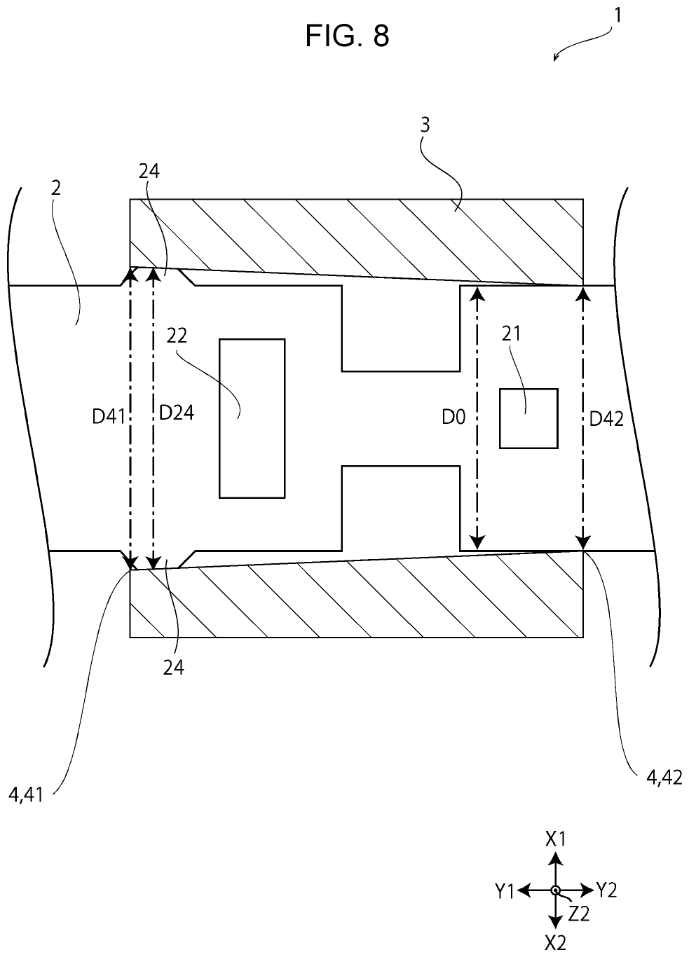

FIG. 8 is a plan view of the current sensor 1 according to the embodiment schematically illustrating a structure that may be provided to suppress the occurrence of misalignment of the busbar 2 in the X direction. As illustrated in the drawing, in the insertion hole 4, when viewed in the Z direction, which is the stacking direction of the busbar 2 and the magnetic sensor 5, a width dimension D41 of the opening 41 may be greater than a width dimension D42 of the opening 42, and the width dimension may be increased from the opening 42 toward the opening 41.

The busbar 2 may include, in a state in which the second protruding portion 22 of the busbar 2 engages with the stopper portion 32 (see FIG. 6A and FIG. 6B), at portions in the insertion hole 4 and near the opening 41, a fitting protruding portion 24 that protrudes in the width direction (X direction) of the busbar 2 on each side of the busbar 2 in the width direction (X direction) of the busbar 2.

The width dimension D42 of the opening 42 is approximately the same as a width dimension DO of the busbar 2 at a portion where the fitting protruding portion 24 is not provided, and the width dimension D41 of the opening 41 is approximately the same as a width dimension D24 of the busbar 2 including the fitting protruding portion 24.

With the above-described structure illustrated in FIG. 8, in a state in which the second protruding portion 22 of the busbar 2 engages with the stopper portion 32, the opening 41 and the opening 42 on both sides of the insertion hole 4 fit together with the busbar 2, and thereby the busbar 2 can be positioned in the X direction in the main body 3.

### Second Embodiment

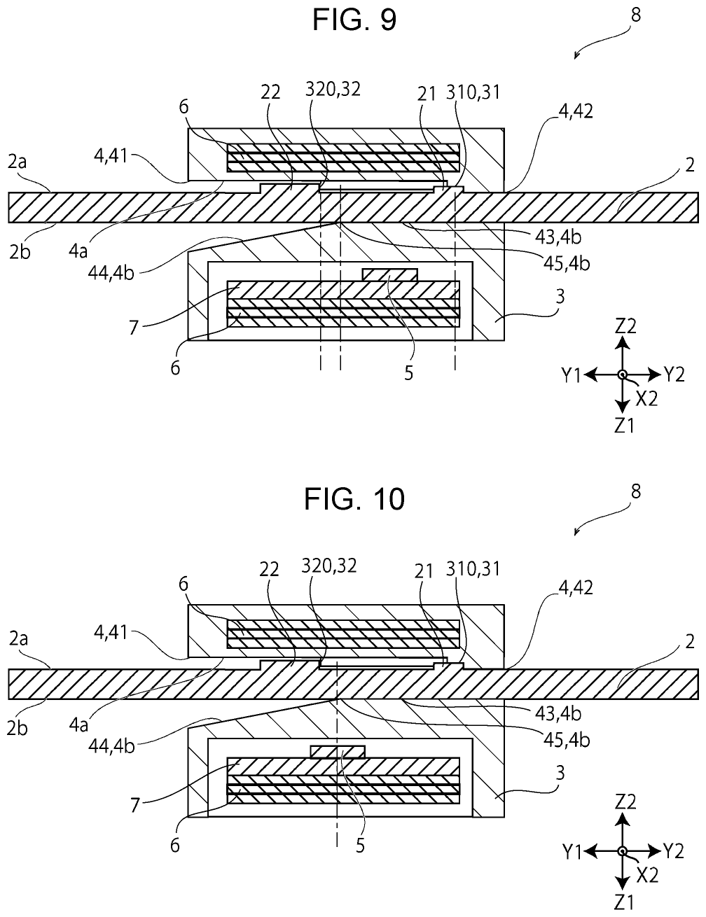

FIG. 9 is a cross-sectional view of a current sensor 8 according to the embodiment. The current sensor 8 differs from the current sensor 1 according to the first embodiment in that the second inner surface 4b of the insertion hole 4, which faces the plate surface 2b of the busbar 2, includes a horizontal portion 43 and a tapered portion 44.

The horizontal portion 43 is a portion that is formed in a plane shape that is parallel to the first inner surface 4a, from the opening 42 in the insertion hole 4 toward the inside of the insertion hole 4 (in the direction from Y2 toward Y1). The horizontal portion 43 is parallel to the plate surface 2b of the busbar 2 in a state in which the busbar 2 is attached at a predetermined position in the main body 3.

The tapered portion 44 is a portion that is formed such that the distance with respect to the first inner surface 4a becomes shorter from the opening 41 in the insertion hole 4 toward the inside of the insertion hole 4 (in the direction from Y1 toward Y2). The tapered portion 44 is inclined with respect to the plate surface 2b of the busbar 2 in a state in which the busbar 2 is attached. The tapered portion 44 is formed such that the distance with respect to the plate surface 2b of the busbar 2 in the insertion hole 4 becomes shorter as the tapered portion 44 extends toward the inside of the insertion hole 4. In other words, the tapered portion 44 is formed such that, in a state in which the busbar 2 is attached at the predetermined position in the main body 3, the distance with respect to the plate surface 2b of the busbar 2 becomes shorter in the direction toward the inside of the insertion hole 4.

The horizontal portion 43 and the tapered portion 44 are adjacent to each other with a boundary ridge line 45 therebetween. In other words, the horizontal portion 43 and the tapered portion 44 are continuously provided with the boundary ridge line 45 as the boundary. The boundary ridge line 45 is located between the first protruding portion 21 and the second protruding portion 22 of the busbar 2 in the Y direction, which is the extending direction of the busbar 2, in a state in which the busbar 2 is attached at the predetermined position in the main body 3. In other words, the boundary ridge line 45 is formed to be located between a contact portion 320 in the stopper portion 32 at which the contact portion 320 is in contact with the second protruding portion 22 of the busbar 2 and a tightly fitted portion 310 in the crush rib 31 at which the tightly fitted portion 310 is tightly fitted with the first protruding portion 21 of the busbar 2.

When the crush rib 31 softens over time due to high temperature environments, vibration, or other factors and the function of positioning the busbar 2 in the Z direction decreases, an end portion of the busbar 2 on the Y1 side may be inclined toward the Z1 side due to the attachment orientation of the current sensor 8. The boundary ridge line 45 functions as a fulcrum when the busbar 2 is inclined as described above. Specifically, when the busbar 2 is inclined, the plate surface 2b of the busbar 2 moves away from the horizontal portion 43; however, the separation distance is zero at the boundary ridge line 45, and the separation distance becomes smaller as the distance with respect to the boundary ridge line 45 decreases. The portion of the busbar 2 facing the magnetic sensor 5 is located near the boundary ridge line 45, and therefore a change in the distance between the magnetic sensor 5 and the busbar 2 when the busbar 2 is inclined can be reduced.

In addition, by disposing the magnetic sensor 5 at the position the magnetic sensor 5 overlaps the stopper portion 32 when viewed in the Z direction, the movement of the Y1 side end of the busbar 2 in the Z2 direction can be regulated by the stopper portion 32. By reducing the amount of displacement between the magnetic sensor 5 and the busbar 2, the amount of change in the distance between the magnetic sensor 5 and the busbar 2 when the busbar 2 is inclined can be reduced. Accordingly, a decrease in measurement accuracy of the current sensor 8 caused by a change in the distance between the magnetic sensor 5 and the busbar 2 can reduced.

### Modification

FIG. 10 is a cross-sectional view of the current sensor 8 according to a modification. The current sensor 8 according to the modification illustrated in the drawing differs from the current sensor 8 in FIG. 9 in that, when viewed in the Z direction in which the busbar 2 and the magnetic sensor 5 are stacked, the magnetic sensor 5 is disposed at a position the magnetic sensor 5 overlaps the boundary ridge line 45 and the stopper portion 32. With this structure, the magnetic sensor 5 is disposed in the vicinity of the boundary ridge line 45, which functions as the fulcrum when the end portion of the busbar 2 on the Y1 side is inclined toward the Z1 side, and the amount of change in the distance between the magnetic sensor 5 and the busbar 2 can be further reduced.

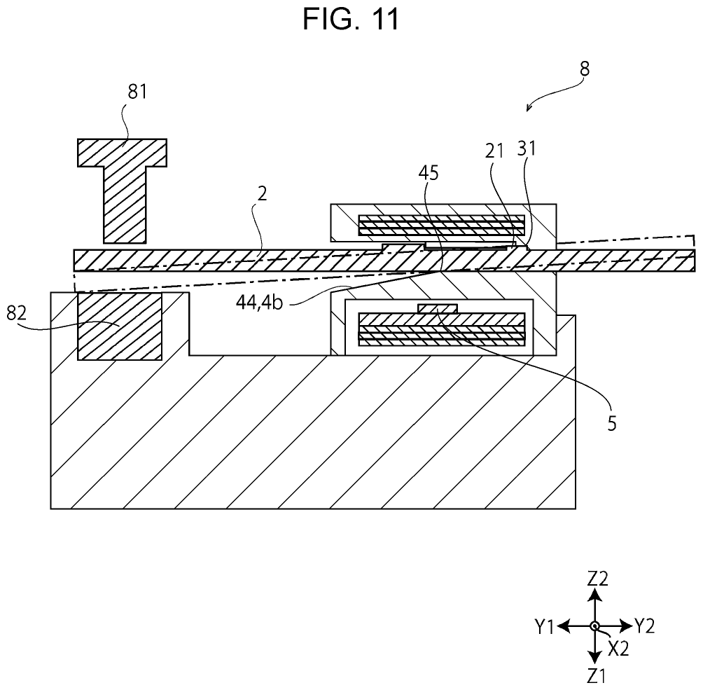

FIG. 11 is a cross-sectional view schematically illustrating the busbar 2 in the current sensor 8 according to a modification, the busbar 2 to be fastened to a stepped portion. As illustrated in the drawing, when the end portion of the busbar 2 on the Y1 side is fastened to a fastening portion 82 by using a fastening means 81, a force in the Z1 direction is applied to the end portion of the busbar 2 on the Y1 side, and the busbar 2 may be inclined as indicated by the alternating long and short dashed lines. In such a case, since the tapered portion 44 is provided, the busbar 2 is inclined with the boundary ridge line 45 as the fulcrum. Specifically, even if the busbar 2 is inclined in the vicinity of the boundary ridge line 45, the relative position between the busbar 2 and the boundary ridge line 45 remains almost unchanged, thereby reducing the amount of displacement of the busbar 2 at the portion in the vicinity of the boundary ridge line 45. Accordingly, when the current sensor 8 is to be attached as illustrated in FIG. 11, by disposing the magnetic sensor 5 in the vicinity of the boundary ridge line 45, effects of the misalignment between the busbar 2 and the magnetic sensor 5 can be more effectively reduced.

As the misalignment between the busbar 2 and the magnetic sensor 5 decreases, the measurement error of the current sensor 8 can be reduced. It should be noted that in the busbar 2 indicated by the alternating long and short dashed lines in FIG. 11, the end of the busbar 2 on the Y1 side is attached to the fastening portion 82 by using the fastening means 81, and the tight fitting between the first protruding portion 21 and the crush rib 31 is loosened. When the first protruding portion 21 and the crush rib 31 are kept in the tightly fitted state, the end portion of the busbar 2 on the Y2 side maintains the same state as the busbar 2 indicated by the solid line in FIG. 11.

### EXAMPLES

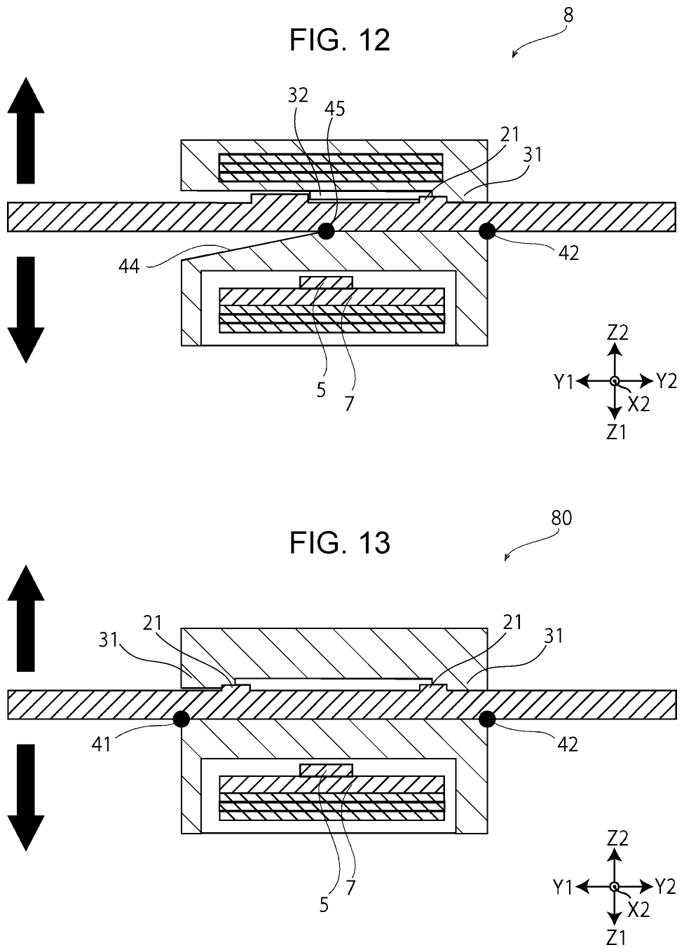

FIG. 12 is a cross-sectional view of the current sensor 8, the view illustrating a simulation method in the example. As illustrated in the drawing, for the current sensor 8 according to the modification of the second embodiment, a simulation of displacement in the busbar 2 and the substrate 7, on which the magnetic sensor 5 was disposed, when the end portion of the busbar 2 on the Y1 side was moved in the Z1 direction or the Z2 direction was performed. Evaluation of displacement by simulation was performed for cases in which the crush rib 31 had no damage, and for cases in which the crush rib 31 had damage.

FIG. 13 is a cross-sectional view of a current sensor 80 according to a comparative example. As illustrated in the drawing, for the current sensor 80 that had the crush rib 31 on both sides in the Y direction with the magnetic sensor 5 therebetween, a simulation was performed under the same conditions as for the current sensor 8 in FIG. 12.

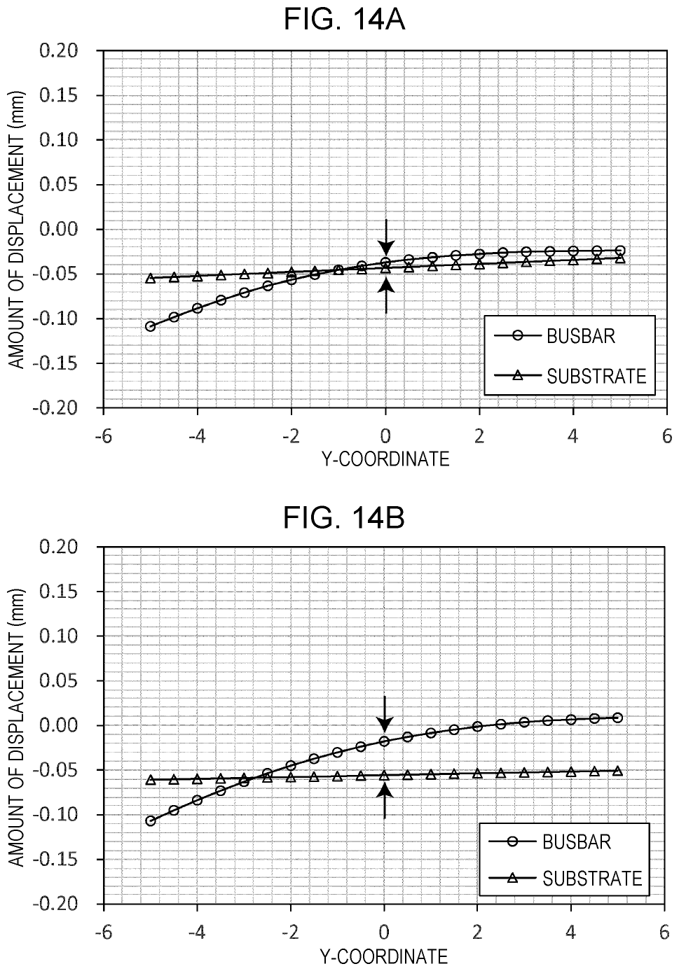

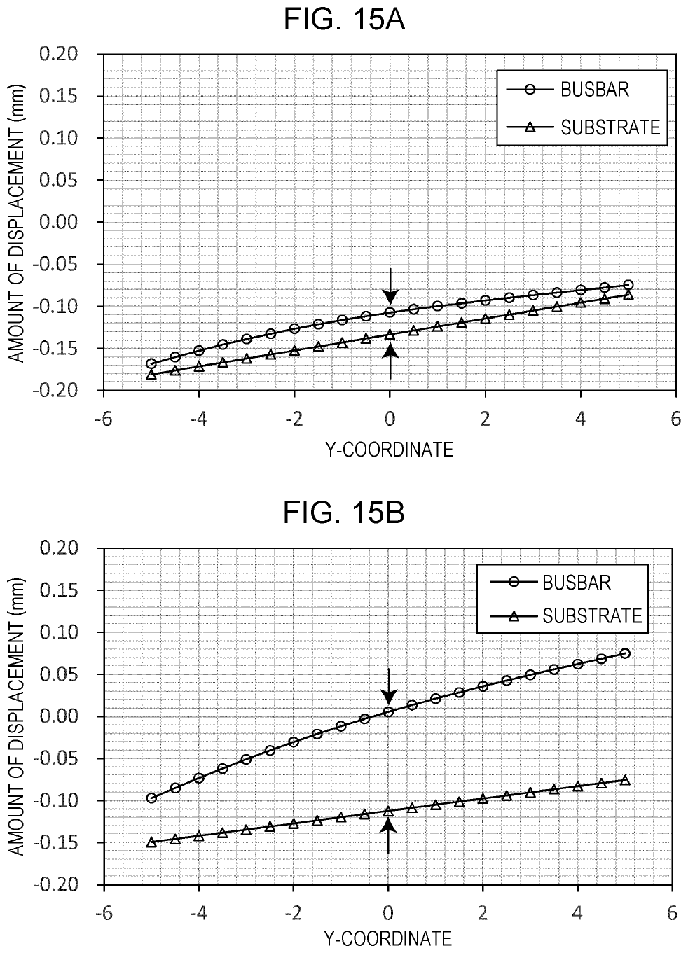

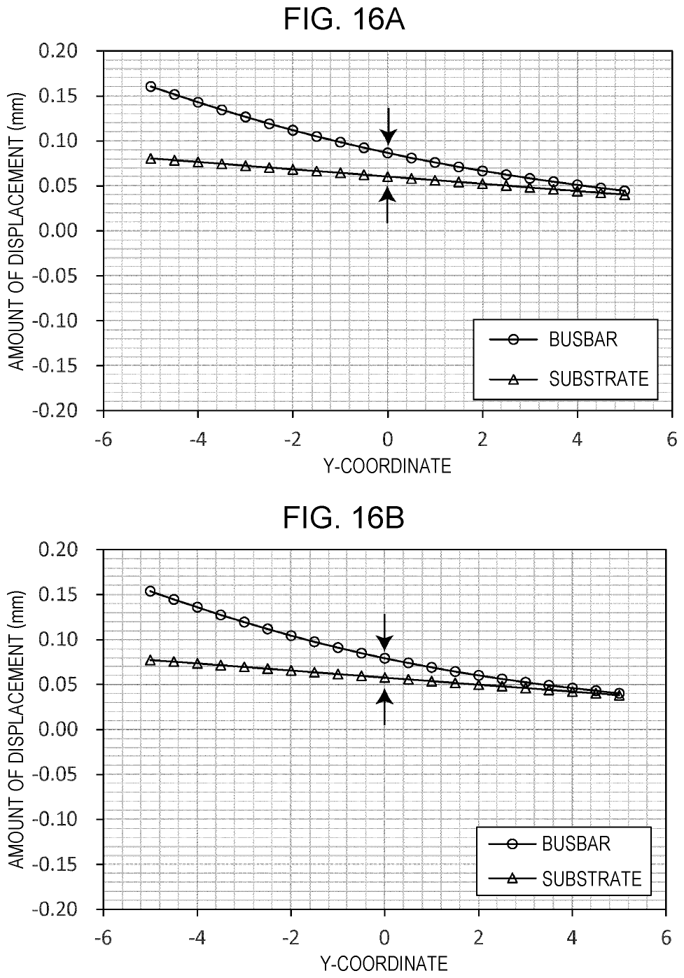

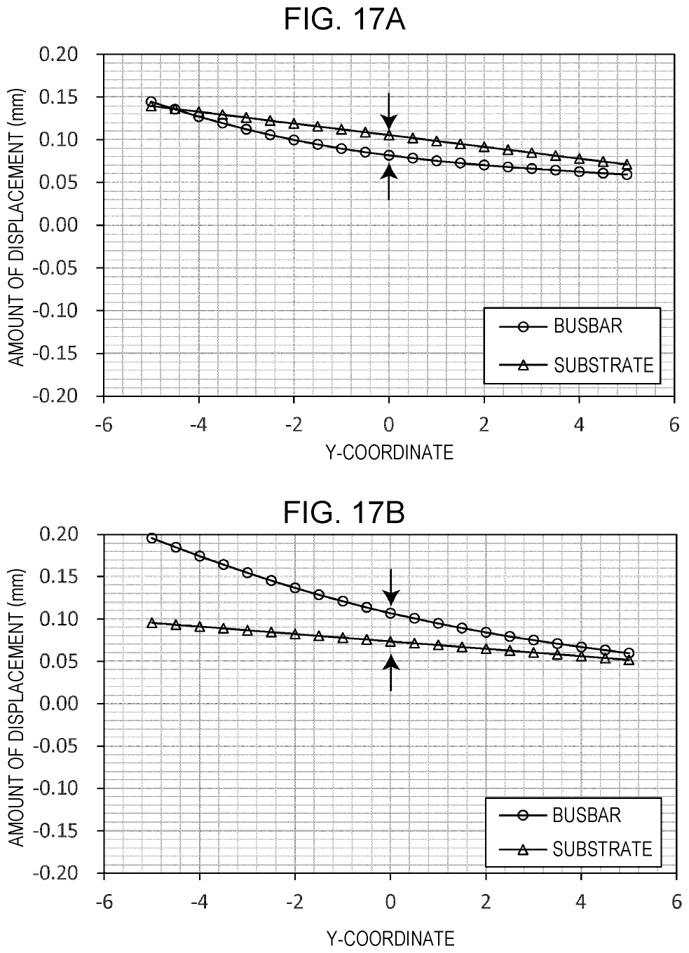

FIG. 14A and FIG. 14B show simulation results of the embodiment in which the busbar 2 was moved in the Z1 direction in a case in which the crush rib 31 had no damage and in a case in which the crush rib 31 had damage. FIG. 15A and FIG. 15B show simulation results of the comparative example in which the busbar 2 was moved in the Z1 direction in a case in which the crush rib 31 had no damage and in a case in which the crush rib 31 had damage. In each graph, the Y-coordinate 0 represents the position on the substrate 7 where the magnetic sensor 5 was disposed, and the difference in the output values indicated by the arrows shows a relative amount of displacement amount between the busbar 2 and the magnetic sensor 5 (the same applies to FIG. 16A to FIG. 17B).

When the end portion of the busbar 2 on the Y1 side was moved in the Z1 direction, regardless of whether or not the crush rib 31 had damage, the amount of displacement between the busbar 2 and the magnetic sensor 5, which was disposed on the substrate 7, in the current sensor 8 according to the embodiment was significantly lower than that in the current sensor 80 according to the comparative example. This result suggests that, by providing the tapered portion 44, the fulcrum when the busbar 2 was displaced moved from the opening 41 indicated by the black circle in FIG. 13 to the boundary ridge line 45 indicated by the black circle in FIG. 12, and the displacement of the busbar 2 in the vicinity of the boundary ridge line 45 became smaller.

FIG. 16A and FIG. 16B show results of the embodiment in which the busbar 2 was displaced in the Z2 direction in a case in which the crush rib 31 had no damage and in a case in which the crush rib 31 had damage. FIG. 17A and FIG. 17B show results of the comparative example in which the busbar 2 was displaced in the Z2 direction in a case in which the crush rib 31 had no damage and in a case in which the crush rib 31 had damage.

When the end of the busbar 2 on the Y1 side was moved in the Z2 direction, in the case in which the crush rib 31 had no damage, the amount of displacement in the current sensor 8 according to the embodiment was similar to that in the current sensor 80 according to the comparative example. In the case in which the crush rib 31 had damage, the amount of displacement in the current sensor 8 according to the embodiment was slightly reduced compared to that in the current sensor 80 according to the comparative example. As indicated by the black circles in FIG. 12 and FIG. 13, in both of the current sensor 8 according to the embodiment and the current sensor 80 according to the comparative example, the fulcrums when the busbar 2 was displaced were the openings 42. Accordingly, the result obtained when the crush rib 31 had damage suggests that the displacement of the busbar 2 in the current sensor 8 according to the embodiment was suppressed by the stopper portion 32.

To summarize the results of the simulation described above, the following conclusions can be drawn. In the current sensor 8 according to the embodiment, when the end of the busbar 2 on the Y1 side was moved in the Z1 direction, the busbar 2 was inclined with the boundary ridge line 45 as the fulcrum. Accordingly, as the magnetic sensor 5 is disposed at a position closer to the position facing the boundary ridge line 45, the amount of displacement between the magnetic sensor 5 and the busbar 2 can be reduced. When the end of the busbar 2 on the Y1 side was moved in the Z2 direction, the busbar 2 was inclined with the end portion on the Z1 side in the opening 42 as the fulcrum. Accordingly, as the magnetic sensor 5 is disposed at a position closer to the position facing the end portion on the Z1 side in the opening 42, the amount of displacement between the magnetic sensor 5 and the busbar 2 can be reduced. Thus, when the magnetic sensor 5 is disposed at the position facing the area between the boundary ridge line 45 and the opening 42, it is unlikely that the amount of displacement between the busbar 2 and the magnetic sensor 5 becomes very large, even if the end of the busbar 2 on the Y1 side is moved in either the Z1 direction or the Z2 direction. Accordingly, by disposing the magnetic sensor 5 at the position facing the area between the boundary ridge line 45 and the opening 42, even if the position of the busbar 2 varies in the Z direction, measurement error of the current sensor 8 can be reduced.

The embodiments disclosed in this specification are in all respects illustrative and not limited to these embodiments. The scope of the invention is defined by the claims, but is not defined by the description of only the above embodiments, and is intended to include all modifications within the meaning and scope equivalent to the claims.

The present invention is useful, for example, as a current sensor that is used to measure currents to be measured flowing through various devices used to control power systems or other components of vehicles.

What is claimed is:

1. A current sensor comprising:
a magnetic sensor configured to detect a magnetic field generated by a busbar when a current to be measured flows; and
a main body accommodating the magnetic sensor, wherein
the main body includes
an insertion hole into which the busbar is insertable,
a stopper portion configured to engage the busbar inserted into the insertion hole in the busbar at a predetermined position in a longitudinal direction, and
a crush rib configured to fit tightly with a first protruding portion protruding from one plate surface of the busbar, in a state in which the busbar engages with the stopper portion.

2. The current sensor according to claim 1, wherein
the stopper portion protrudes from a first inner surface in an inner surface of the insertion hole, the first inner surface facing the one plate surface of the busbar, and
the stopper portion engages with the busbar when the stopper portion comes into contact with a second protruding portion protruding from the one plate surface of the busbar.

3. The current sensor according to claim 1, wherein the stopper portion is an opening surface surrounding an opening of the insertion hole, and engages with the busbar when the stopper portion comes into contact with a second protruding portion protruding from an end surface of the busbar in a width direction.

4. The current sensor according to claim 1, wherein
in a state in which the stopper portion engages with the busbar at the predetermined position,
the magnetic sensor is located to face the other plate surface of the busbar.

5. The current sensor according to claim 4, wherein
a second inner surface in an inner surface of the insertion hole, the second inner surface facing the other plate surface of the busbar, has
a horizontal portion formed in a plane shape parallel to a first inner surface having the crush rib, the horizontal portion extending from one opening in the insertion hole toward the inside of the insertion hole, and
a tapered portion that is formed such that a distance with respect to the first inner surface becomes shorter, from the other opening of the insertion hole toward the inside of the insertion hole,
the horizontal portion and the tapered portion are adjacent to each other with a boundary ridge line therebetween, and
the boundary ridge line is provided, in an extending direction of the busbar, between a contact portion at which the stopper portion comes into contact with the busbar and a tightly fitted portion at which the crush rib is tightly fitted with the busbar.

6. The current sensor according to claim 5, wherein when viewed in a direction in which the busbar and the magnetic sensor are stacked, the boundary ridge line overlaps the magnetic sensor.

7. The current sensor according to claim 5, wherein when viewed in a direction in which the busbar and the magnetic sensor are stacked, the stopper portion, the boundary ridge line, and the magnetic sensor overlap each other.

8. A current sensor comprising:
an elongated plate-shaped busbar through which a current to be measured flows;
a magnetic sensor configured to detect a magnetic field generated by the busbar when the current to be measured flows; and
a main body accommodating the magnetic sensor, wherein
the busbar includes
a first protruding portion protruding from one plate surface, and
an engaging portion configured to engage the busbar inserted into an insertion hole at a predetermined position,
the main body includes
the insertion hole into which the busbar is insertable,
a crush rib configured to fit tightly with the first protruding portion of the busbar, the crush rib formed in a first inner surface inside the insertion hole, the first inner surface facing the one plate surface of the busbar, and
a stopper portion configured to engage with the engaging portion of the busbar, and
by inserting the busbar into the insertion hole,
the first protruding portion and the crush rib tightly fit with each other, the engaging portion and the stopper portion come in contact with each other, and in a state in which the magnetic sensor is located to face the other plate surface of the busbar, the busbar is attached to the main body.

9. The current sensor according to claim 8, wherein
the busbar includes a fitting protruding portion that protrudes in a width direction of the busbar at a portion where the fitting protruding portion is disposed in the insertion hole and near the other opening, in a state in which the busbar is inserted into the insertion hole and the engaging portion of the busbar engages with the stopper portion, and
the insertion hole of the main body is formed such that a dimension in a width direction increases from one opening toward the other opening, the width dimension of the one opening is approximately the same as the width dimension of the busbar at a portion in which the fitting protruding portion is not provided, and the width dimension of the other opening is approximately the same as the width dimension of the busbar including the fitting protruding portion.

10. The current sensor according to claim 8, wherein
the busbar includes a narrow portion between the first protruding portion and the engaging portion, the narrow portion being narrower in a width dimension than other portions, and
the magnetic sensor is disposed at a position facing the narrow portion.
